(19) United States
(12) Patent Application Publication
(10) Pub. No.: US 2012/0006394 A1
(43) Pub. Date: Jan. 12, 2012

(54) METHOD FOR MANUFACTURING OF ELECTRICAL CONTACTS ON A SOLAR CELL, SOLAR CELL, AND METHOD FOR MANUFACTURING A REAR SIDE CONTACT OF A SOLAR CELL

(75) Inventors: Philipp Richter, Hillsboro, OR (US); Torsten Weber, Dresden (DE)

(73) Assignee: SOLARWORLD INDUSTRIES AMERICA, INC., Hillsboro, OR (US)

(21) Appl. No.: 12/832,123

(22) Filed: Jul. 8, 2010

(51) Int. Cl. H01L 31/0224; H01L 31/18

(52) U.S. Cl. 136/256; 438/98; 257/E31.124

(57) ABSTRACT

In various embodiments, a method for manufacturing of electrical contacts on a solar cell is provided. The method may include forming a dielectric layer on a region to be electrically contacted; forming a first metal layer over the dielectric layer; forming electrical contacts between the first metal layer and the region to be electrically contacted through the dielectric layer by laser pulses; annealing the formed electrical contacts; and forming a second metal layer comprising a solderable material at least over a portion of the first metal layer.

### TECHNICAL FIELD

Various embodiments relate to a method for manufacturing of electrical contacts on a solar cell, a solar cell, and a method for manufacturing a rear side contact of a solar cell.

### BACKGROUND

A high degree of efficiency, in other words a high current yield, is usually desired in a solar cell. In a conventional solar cell, electrical contacts are provided on the rear side of a solar cell. In a conventional process of manufacturing electrical contacts on a solar cell, a contacting metal layer made of aluminum or silver is deposited on a passivation layer on the rear side of the solar cell. Furthermore, a layer of an as such solderable material (Ag, Ni, NiV, NiCr, and Cr) is sputtered on the contacting metal layer. In the conventional process, there is no break in the vacuum atmosphere between the deposition of the contacting metal layer and the sputtering of the layer of an as such solderable material. In the conventional process, after the deposition of both layers, a laser fired contact (LFC) process is carried out to provide electrical contacts between the contacting metal layer and the base region of the solar cell through the passivation layer.

### SUMMARY

In various embodiments, a method for manufacturing of electrical contacts on a solar cell is provided. The method may include forming a dielectric layer on a region to be electrically contacted; forming a first metal layer over the dielectric layer; forming electrical contacts between the first metal layer and the region to be electrically contacted through the dielectric layer by laser pulses; annealing the formed electrical contacts; and forming a second metal layer comprising a solderable material at least over a portion of the first metal layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a cross sectional view of a solar cell at a first stage of the formation of electrical rear side contacts in accordance with an embodiment;

FIG. 2 shows a cross sectional view of a solar cell at a second stage of the formation of electrical rear side contacts in accordance with an embodiment;

FIG. 3 shows a cross sectional view of a solar cell at a third stage of the formation of electrical rear side contacts in accordance with an embodiment;

FIG. 4 shows a cross sectional view of a solar cell at a fourth stage of the formation of electrical rear side contacts in accordance with an embodiment;

FIG. 5 shows a cross sectional view of a solar cell at a fifth stage of the formation of electrical rear side contacts in accordance with an embodiment;

FIG. 6 shows a cross sectional view of a solar cell at a sixth stage of the formation of electrical rear side contacts in accordance with an embodiment;

FIG. 7 shows a cross sectional view of a solar cell at a seventh stage of the formation of electrical rear side contacts in accordance with an embodiment;

FIG. 8 shows a cross sectional view of a solar cell at an eighth stage of the formation of electrical rear side contacts in accordance with an embodiment;

FIG. 9 shows a cross sectional view of a solar cell at a ninth stage of the formation of electrical rear side contacts in accordance with an embodiment;

FIG. 10 shows a cross sectional view of a solar cell at a tenth stage of the formation of electrical rear side contacts in accordance with an embodiment;

FIG. 11 shows a cross sectional view of a solar cell at an eleventh stage of the formation of electrical rear side contacts in accordance with an embodiment;

FIG. 12 shows a plurality of solar cells electrically coupled via contact wires in accordance with an embodiment; and

FIG. 13 shows a flow diagram illustrating a method for manufacturing of electrical contacts on a solar cell in accordance with an embodiment.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various embodiments provide for a procedure for rear side metallization of a dielectrically passivated local contact solar cell with a deposition of a solderable layer, in other words a layer including or made of a solderable material, after the formation and annealing of the electrical rear side contacts, e.g. after applying laser pulses (e.g. by carrying out a laser fired contact (LFC) process) to form the electrical rear side contacts and after the subsequent anneal process.

In various embodiments, a two-step rear side metallization for LFC solar cells is provided, wherein e.g. a first metal layer (which may also be referred to as the contacting layer) is deposited on a rear side dielectric layer (e.g. in a vacuum process), then the vacuum is broken and the laser pulses are applied to form the electrical rear side contacts through the dielectric layer, followed by an annealing of the structure. The second metal layer is then deposited after the anneal process. The second metal layer may include or consist of solderable material.

In various embodiments, a solar cell may be understood as being a device which directly converts light energy (e.g. at least a portion of the light in the visible wave length region in the range from about 300 nm to about 1150 mn, e.g. sunlight) into electrical energy by means of the so called photovoltaic effect.

In various embodiments, in a process of manufacturing and wiring a solar cell, a wafer (e.g. made of silicon or any other suitable material as listed below), may be separated (e.g. sawn) into individual pieces, e.g. the solar cells. Then, the damages caused by the separation (e.g. sawing) process may be removed and the separated solar cells may be cleaned.

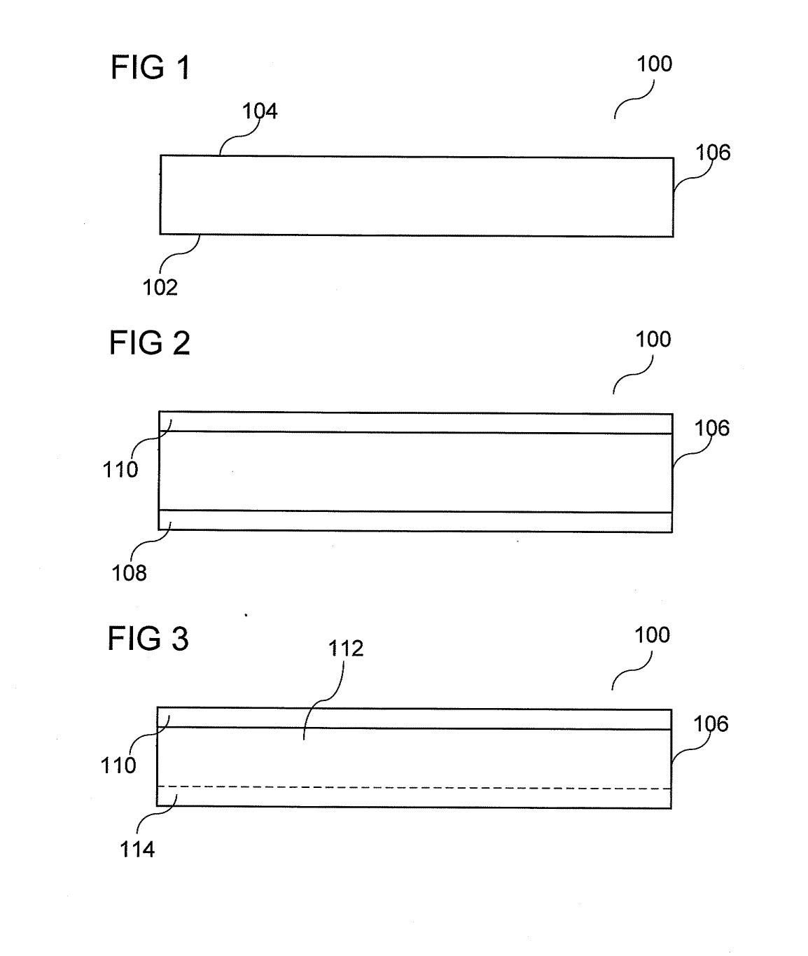

FIG. 1 shows a cross sectional view of a solar cell 100 at a first stage of the formation of electrical rear side contacts in accordance with an embodiment. As shown in FIG. 1, the solar cell 100 may include a front surface 102 and a rear surface 104. It is to be noted that the solar cell is shown in FIG. 1 upside down, i.e. the rear surface 104 is arranged in the upward-direction in FIG. 1 and the front surface 102 is arranged in the downward-direction in FIG. 1.

In various embodiments, solar cells (e.g. including the solar cell 100), which may be formed in or on a wafer, e.g. a semiconductor wafer, may be electrically connected to each other to e.g. be encapsulated as a solar module. A solar module may include a glass layer on its front side (i.e. the sunny side, also referred to as the emitter side), which allows light impinging onto the solar module to pass the glass layer, while at the same time it protects the wafer or the solar cells from being damaged, e.g. due to rain, hail, snow, and the like.

In various embodiments, the solar cell 100 may have the following dimensions: a width in the range from about 10 cm to about 50 cm, a length in the range from about 10 cm to about 50 cm, and a thickness in the range from about 50 μm to about 300 μm.

In various embodiments, the solar cell 100 may include at least one photovoltaic layer 106 (e.g. as a part of a layer structure having one or more layers). The at least one photovoltaic layer 106 may include or consist of a semiconductor material (such as e.g. silicon), a compound semiconductor material (such as e.g. a III-V-semiconductor material (such as e.g. GaAs), a II-VI-semiconductor material (such as e.g. CdTe), or a I-III-V-semiconductor material (such as e.g. CuInS₂). In various embodiments, the at least one photovoltaic layer 106 may include or consist of an organic material. In various embodiments, the silicon may include or consist of single-crystalline silicon, poly-crystalline silicon, amorphous silicon, and/or micro-crystalline silicon. The at least one photovoltaic layer 106 may include or consist of a junction such as e.g. a pn-junction, a pin-junction, a Schottky-type junction, and the like, as will be described in more detail below. In various embodiments, the at least one photovoltaic layer 106 may have a layer thickness in the range from about 50 μm to about 300 μm, e.g. a layer thickness in the range from about 100 μm to about 200 μm, e.g. a layer thickness in the range from about 150 μm to about 180 μm.

In various embodiments, as will be described in more detail below, the rear side 104 of the solar cell 100 may include a rear side electrode. The rear side electrode may include or consist of electrically conductive material, e.g. one or more metals. In various embodiments, the rear side electrode may be transparent. Furthermore, in various embodiments, the rear side electrode may be patterned.

As will also be described in the following, in various embodiments, an electric contacting structure, e.g. implemented in the form of a plurality of metallization lines, in other words, metallization conductors (e.g. in the form of contact fingers), may be provided on or above the front surface 102 of the at least one photovoltaic layer 106. The metallization lines may run substantially parallel to one another and/or at a distance from each other. However, it is to be noted that the metallization lines may alternatively run at an angle to each other, but without crossing each other. In various embodiments, the metallization lines may be provided in a comb structure having a plurality of metal fingers, which run substantially parallel to each other. In various embodiments, the metallization lines may be provided in a strip shape electrically conductive surface regions. In various embodiments, the electric contacting structure may e.g. be implemented in the form of a plurality of electrically conductive point contacts.

In various embodiments, the layer structure including the at least one photovoltaic layer 106 which may be p-doped (e.g. using boron as doping species).

In various embodiments, it is achieved to provide of a solderable layer at the rear of an LFC solar cell.

The inventors have realized that the conventional processing sequence as described above, namely to sputter or by means of E-beam evaporation or thermal evaporation an aluminum and nickel vanadium layer structure followed by the lasering and the anneal process may result in at least one of the following problems:
The nickel vanadium is diffused into the bulk of the at least one photovoltaic layer 106 by the laser impact, and acts as a recombination center therein that lowers the open circuit voltage Voc and the open circuit current of solar cell.
The annealing parameters, such as e.g. annealing temperature and annealing time, of the rear side contacts is limited by the need to maintain the solderability of the nickel vanadium layer; the nickel vanadium oxidises and becomes unsolderable.
The laser contact quality with a current laser source and parameters is poor. This may result in insufficient conductance from the bottom of contact to its surrounding metal layer.
A better contact resistance can conventionally be achieved only with deeper holes that reduce solderability of the rear side because of additional debris on top of solderable layer.

FIG. 2 shows a cross sectional view of a solar cell 100 at a second stage of the formation of electrical rear side contacts in accordance with an embodiment.

As shown in FIG. 2, both sides 102, 104 of the at least one photovoltaic layer 106 of the solar cell 100 may be oxidized, thereby forming thin oxide layers (e.g. silicon oxide layers) 108, 110. The oxide layers (e.g. silicon oxide layers) 108, 110 may have a layer thickness in the range from about 5 nm to about 200 nm, e.g. a layer thickness in the range from about 10 nm to about 150 nm, e.g. a layer thickness in the range from about 50 nm to about 100 nm.

FIG. 3 shows a cross sectional view of a solar cell 100 at a third stage of the formation of electrical rear side contacts in accordance with an embodiment.

As shown in FIG. 3, in a next process stage, the thin oxide layer (e.g. silicon oxide layer) 108 on the front side 102 of the solar cell 100 may be removed in various embodiments. Then, the front side 102 may be textured and a diffusion process (e.g. a phosphorous diffusion process) may be carried out to form a base region 112 (which may still be p-doped) and an emitter region 114 (which may be n-doped, e.g. using phosphorous as doping species). The interface between the base region 112 and the emitter region 114 may together form a pn-junction for generating electrical energy. It is to be noted that alternative processes to form the emitter region 114 may be provided in alternative embodiments, such as e.g. laser doping or epitaxy of phosphor-doped silicon. Furthermore, phosphorous glass possibly formed during the diffusion process may be removed from both sides 102, 104 of the solar cell 100 in various embodiments (not shown). In various embodiments, the base region 112 may in general be the region which should be electrically contacted from the rear side via the rear side contacts, as will be described in more detail below.

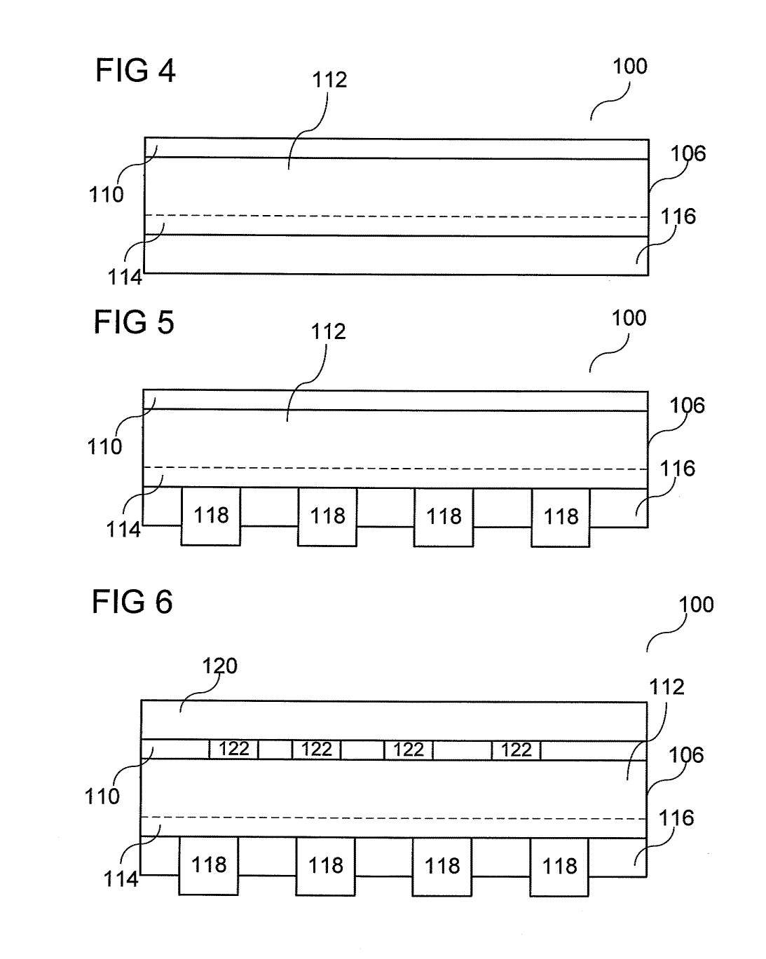

FIG. 4 shows a cross sectional view of a solar cell 100 at a fourth stage of the formation of electrical rear side contacts in accordance with an embodiment.

As shown in FIG. 4, then, a dielectric layer 116, e.g. an anti-reflective layer 116, e.g. including or consisting of silicon, silicon nitride, silicon oxide, silicon carbide, or aluminum oxide, may be deposited on the front side 102 of the solar cell 100 (more precisely, on the exposed surface of the emitter region 114). Other suitable materials may be provided in alternative embodiments for the dielectric layer 116. In various embodiments, the dielectric layer 116 may be formed by means of thermal deposition, atomic layer deposition, and/or chemical vapor deposition, or sputtering.

FIG. 5 shows a cross sectional view of a solar cell 100 at a fifth stage of the formation of electrical rear side contacts in accordance with an embodiment.

Then, the above described electric contacting structure 118, e.g. implemented in the form of a plurality of metallization lines 118, in other words, metallization conductors (e.g. in the form of contact fingers), may be provided on or above the front surface 102 of the at least one photovoltaic layer 106, more accurately, on or above the dielectric layer 116. Then, using a (e.g. fast) firing process, the metallization lines 118 are fired through the dielectric layer 116 to thereby form electrical contacts with the emitter region 114.

FIG. 6 shows a cross sectional view of a solar cell 100 at a sixth stage of the formation of electrical rear side contacts in accordance with an embodiment.

Then, in various embodiments, a first metal layer 120, e.g. including or consisting of a metal such as e.g. aluminum; silver; and/or gold, may be deposited on the rear side 104 of the solar cell, more accurately on the exposed surface of the rear side thin oxide layer (e.g. silicon oxide layer) 110, in a vacuum atmosphere (e.g. by plasma treatment in a vacuum atmosphere), e.g. by means of thermal deposition or sputtering. In various embodiments, the first metal layer 120 may be deposited having a layer thickness in the range from about 200 nm to about 4 μm, e.g. having a layer thickness in the range from about 300 nm to about 3 μm, e.g. having a layer thickness in the range from about 500 nm to about 2 μm.

In various embodiments, the first metal layer 120 may be an aluminum layer 120, which may be deposited at a pressure in the range from about 3*10⁻³ mbar to about 5*10⁻⁷ mbar, e.g. at a pressure in the range from about 5*10⁻³ mbar to about 5*10⁻⁶ mbar, e.g. at a pressure in the range from about 1*10⁻⁴ mbar to about 1*10⁻⁵ mbar. The duration of the deposition process may depend on the desired layer thickness of the first metal layer 120 to be deposited. In various embodiments, using the above pressure regime, e.g. when simultaneously processing about 40 solar cells 100 on a common carrier in the process chamber, 2 μm of the first metal layer 120 may be deposited in approximately 50 seconds. Thus, in various embodiments, using the above pressure conditions for the deposition, the deposition process may be carried out for a time duration in the range from about 30 seconds to about 90 seconds or longer, e.g. for a time duration in the range from about 40 seconds to about 60 seconds or longer.

Then, in various embodiments, the vacuum atmosphere may be broken, i.e. the solar cell 100 as shown in FIG. 6 may be taken out of the vacuum atmosphere, e.g. out of the processing chamber(s) provided for the deposition of the first metal layer 120.

Then, laser light, e.g. laser pulses which may have e.g. a pulse duration in the range of nanoseconds to milliseconds, may be applied to the rear side 102 of the solar cell, i.e. for example to the exposed surface of the first metal layer 120 in order to form, e.g. fire, electrical contacts 122 from the first metal layer 118 through the rear side thin oxide layer (e.g. silicon oxide layer) 110 to the rear side of the base region 112 of the solar cell 100. In various embodiments, this process may be implemented as a so called laser fired contact (LFC) process. In various embodiments, this process may be carried out in non-vacuum atmosphere, e.g. at a room atmosphere and at room temperature. In various embodiments, the electrical contacts 122, e.g. the laser fired contacts 122, may be formed only at pre-defined positions, e.g. at those positions, at which no solder pads are to be formed at a later processing stage. This may be achieved by not exposing those positions, at which e.g. solder pads are to be formed, to the irradiated light, e.g. laser light. By way of example, the electrical contacts 122, e.g. the laser fired contacts 122, may be formed only outside the busbar region to be formed.

In various embodiments, the structure with the formed electrical rear side contacts (and thus the formed electrical rear side contacts 122) is annealed. In various embodiments, the anneal process may be carried out e.g. in a forming gas atmosphere or a normal room atmosphere. In various embodiments, the anneal process may be carried out e.g. at a temperature in the range from about 300° C. to about 500° C., e.g. at a temperature in the range from about 350° C. to about 450° C., e.g. at a temperature in the range from about 375° C. to about 425° C. In various embodiments, the anneal process may be carried out for a time duration in the range from about 5 seconds to about 30 minutes, e.g. for a time duration in the range from about 30 seconds to about 20 minutes, e.g. for a time duration in the range from about 1 minute to about 10 minutes.

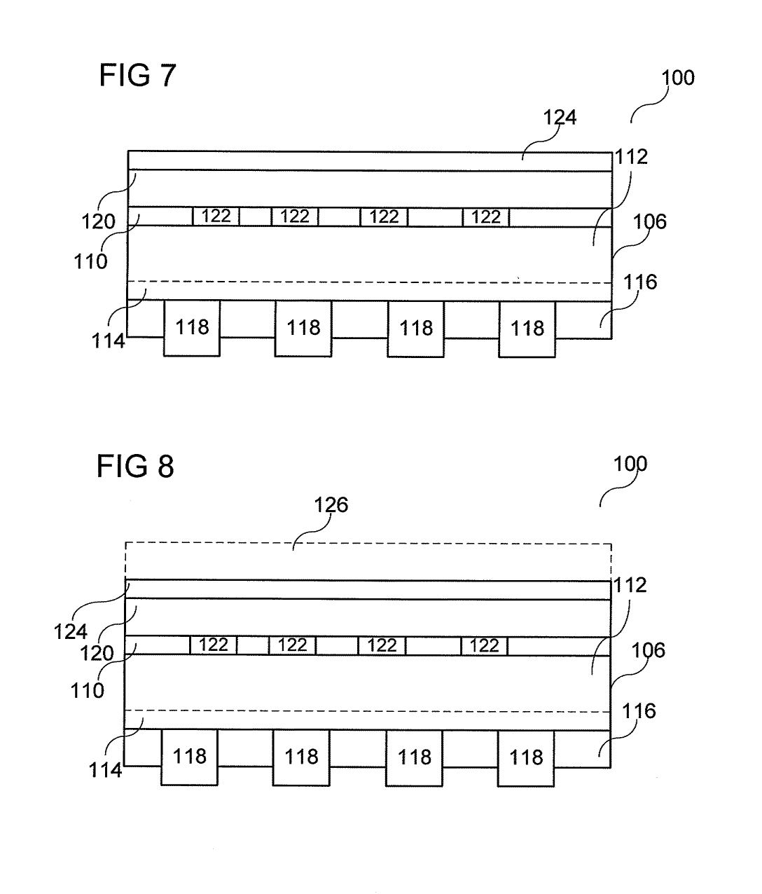

FIG. 7 shows a cross sectional view of a solar cell 100 at a seventh stage of the formation of electrical rear side contacts in accordance with an embodiment.

In various embodiments, due to the optional break of the vacuum atmosphere, as shown in FIG. 7, a first metal oxide layer 124 may be formed on the first metal layer 120 (e.g. an aluminum oxide layer 124 in case the first metal layer 120 is made of aluminum). It is to be noted that in alternative embodiments, the first metal oxide layer 124 may not be formed during and after the LFC process and/or the anneal process (e.g. in embodiments, in which no vacuum break is provided).

Then, as will be described in more detail below, the process for depositing a second metal layer including or consisting of solderable material, will be carried out.

FIG. 8 shows a cross sectional view of a solar cell 100 at an eighth stage of the formation of electrical rear side contacts in accordance with an embodiment.

In those embodiments, in which the first metal oxide layer 124 is formed, a sputter-cleaning from the rear side 104 may be carried out, thereby removing the first metal oxide layer 124 (in general, the first metal oxide layer 124 may be removed in various embodiments by means of a plasma treatment in a vacuum atmosphere). FIG. 8 symbolizes a plasma 126 which is provided in the sputter-cleaning to remove the first metal oxide layer 124. In an alternative embodiment, the first metal oxide layer 124 may be removed using any other suitable process, e.g. by means of etching, such as e.g. by means of wet etching.

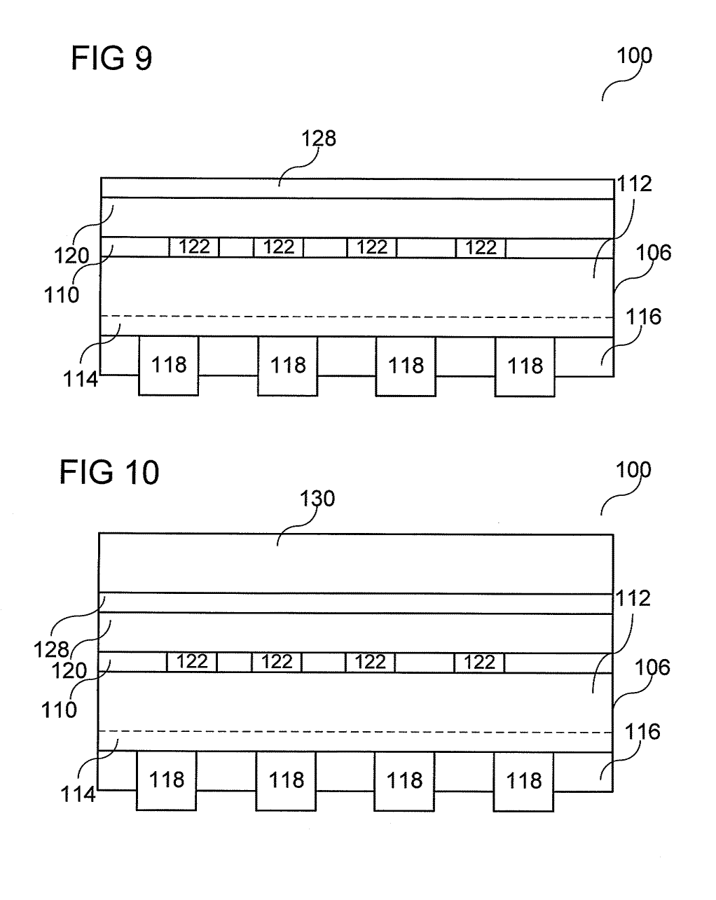

FIG. 9 shows a cross sectional view of a solar cell 100 at a ninth stage of the formation of electrical rear side contacts in accordance with an embodiment.

Then, as shown in FIG. 9, after the optional first metal oxide layer 124 has been removed (or directly after the anneal process, in case no first metal oxide layer 124 is formed), also optionally, a thin layer 128 of the same material (i.e. the first metal) as the material of the first metal layer 120 (e.g. the thin layer 128 may include or consist of aluminum, silver or gold) may be deposited on the exposed surface of the first metal layer 120. The thin layer 128 may be deposited having a layer thickness in the range from about 1 nm to about 50 nm, e.g. a layer thickness in the range from about 5 nm to about 25 nm, e.g. a layer thickness in the range from about 10 nm to about 15 nm. In various embodiments, the optional thin layer 128 may promote the adhesion of the following second metal layer (which may include a plurality of layers) which may include or consist of solderable material. Furthermore, the optional thin layer 128 may decrease the laser contact resistance, in other words the electrical resistance of the electrical contacts 122.

FIG. 10 shows a cross sectional view of a solar cell 100 at a tenth stage of the formation of electrical rear side contacts in accordance with an embodiment.

Then, as shown in FIG. 10, a second metal layer 130 may be deposited on the optional thin layer 128 (or the first metal layer 120, in case the optional thin layer 128 is not present) on the rear side 104 of the solar cell 100. In various embodiments, the second metal layer 130 may include or consist of a solderable material such as e.g. nickel, nickel vanadium, chrome, nickel chrome, silver, gold and the like. In various embodiments, the deposition of the second metal layer 130 may be carried out in a vacuum atmosphere (e.g. by plasma treatment in a vacuum atmosphere), e.g. by means of a sputter process. In various embodiments, the solderable material (e.g. nickel vanadium) of the second metal layer 130 to be formed may be sputtered using a process gas including argon ions and an argon flow e.g. in the range from about 5 sccm to 95 sccm, e.g. in the range from about 10 sccm to 90 sccm, e.g. in the range from about 30 sccm to 70 sccm for a time duration in the range from about 5 seconds to about 5 minutes, e.g. for a time duration in the range from about 30 seconds to about 4 minutes, e.g. for a time duration in the range from about 1 minute to about 3 minutes. The sputtering may be carried out using a sputter power in the range from about 0.5 kW to about 13 kW, e.g. using a sputter power in the range from about 1 kW to about 10 kW, e.g. using a sputter power in the range from about 3 kW to about 7 kW.

In various embodiments, the second metal layer 130 may be deposited having a layer thickness in the range from about 40 nm to about 5 μm, e.g. having a layer thickness in the range from about 100 nm to about 1 μm, e.g. having a layer thickness in the range from about 300 nm to about 500 nm.

In an alternative embodiment, the removal of the first metal oxide layer 124 may be carried out in a common process (i.e. simultaneously) with the deposition of the second metal layer 130. In this case, the above described deposition of the thin layer 128 of the same material (i.e. the first metal) as the material of the first metal layer 120, may be omitted. In various embodiment a sputtering of the second metal layer 130 may be provided to, on the one hand, remove the first metal oxide layer 124 and, on the other hand, to simultaneously deposit the second metal layer 130, which may include or consist of the materials as described above.

In various embodiments, e.g. in the case that the first metal oxide layer 124 has been removed by wet etching, the second metal layer 130 (e.g. including or consisting of nickel vanadium) may also be evaporated (e.g. by means of vapor deposition such as e.g. chemical vapor deposition).

Furthermore, in various embodiments, the second metal layer 130 may include a layer stack of a plurality of layers, e.g. including a titanium layer on the first metal layer 120 or the thin layer 128, and a silver layer on the titanium layer, in which case the titanium layer may act as a diffusion barrier layer with respect to the silver.

In various embodiments, it may be provided that the second metal layer 130 is formed only at pre-defined positions, e.g. at those positions, at which the solder pads are to be formed at a later processing stage. This may be achieved by masking those regions, in which no solder pads are to be formed. In various embodiments, those regions, in which the electrical contacts have been formed, may be masked so that no solderable material is deposited (e.g. sputtered) in those regions. In various embodiments, various masks may be used, e.g. a strip mask or a shadow mask. Illustratively, in various embodiments, the lasered areas may be masked during the deposition of the second metal layer 130.

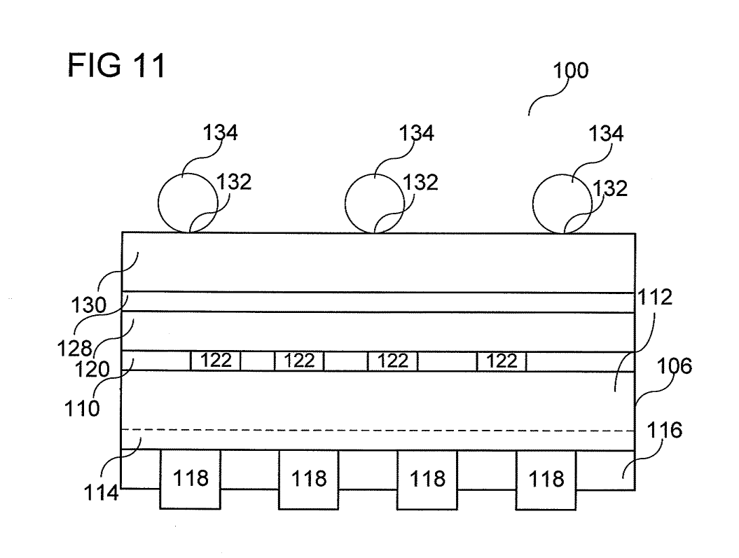

FIG. 11 shows a cross sectional view of a solar cell 100 at an eleventh stage of the formation of electrical rear side contacts in accordance with an embodiment.

Then, as shown in FIG. 11, during the wiring and coupling of a plurality of solar cells 100, contact wires 134 may be positioned on or above the rear side 102 of the solar cell 100, e.g. on or above the second metal layer 130. Then, a solder process may be carried out to form solder contacts 132 between the contact wires 134 and the second metal layer 130, for example. In general, an arbitrary number of contact wires 134 (e.g. at least three contact wires, e.g. 3 contact wires to 90 contact wires, e.g. 5 contact wires to 50 contact wires) may be provided for the coupling of the solar cells 100. In various embodiments, the contact wires 134 may be configured to collect and transmit electrical energy, e.g. electrical current, which is generated from the respective solar cell 100. The contact wires 134 may include or consist of electrically conductive material such as e.g. metallically conductive material, which may include or consist of one or more of the following metals: Cu, Al, Au, Pt, Ag, Pb, Sn, Fe, Ni, Co, Zn, Ti, Mo, W, und/oder Bi. In various embodiments, the contact wires 134 may include or consist of a metal selected from a group consisting of: Cu, Au, Ag, Pb and Sn. In various embodiments, the contact wires 134 may at least partially be coated with a solderable material. The solderable material may include e.g. tin, nickel or silver.

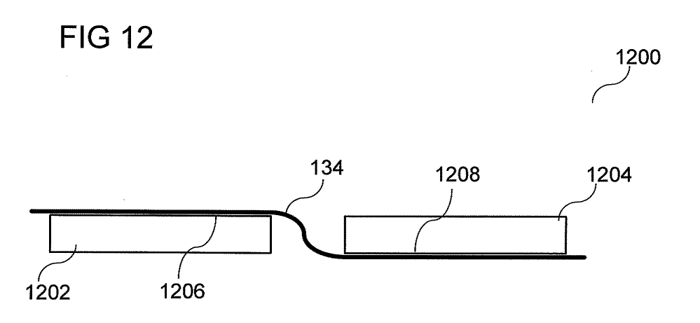

FIG. 12 shows a solar module 1200 including plurality of solar cells 1202, 1204 electrically coupled via contact wires in accordance with an embodiment in a simplified manner. For reasons of simplicity, only two solar cells 1202, 1204, a first solar cell 1202 and a second solar cell 1204, are shown. The solar cells 1202, 1204 may be configured in the same manner as the solar cell 100 described above. In various embodiments, the contact wires 134 are coupled with the contacting structure 118 on the front side 102, 1206 of the first solar cell 1202, and connected to the rear side 104, 1208 of the second solar cell 1204 to thereby provide a serial connection of the solar cells 1202, 1204. By serially coupling more solar cells in a similar manner, a solar cell string is formed, e.g. having a solar cell string length of about 3 solar cells to about 40 solar cells being serially coupled, e.g. having a solar cell string length of about 5 solar cells to about 15 solar cells being serially coupled, e.g. having a solar cell string length of about 10 solar cells being serially coupled. The solar cells may be arranged in the solar module 1200 in various ways. In various implementations, the solar cells may be arranged in longitudinal direction and/or in lateral direction. In various implementations, the solar cells may be connected in parallel with each other.

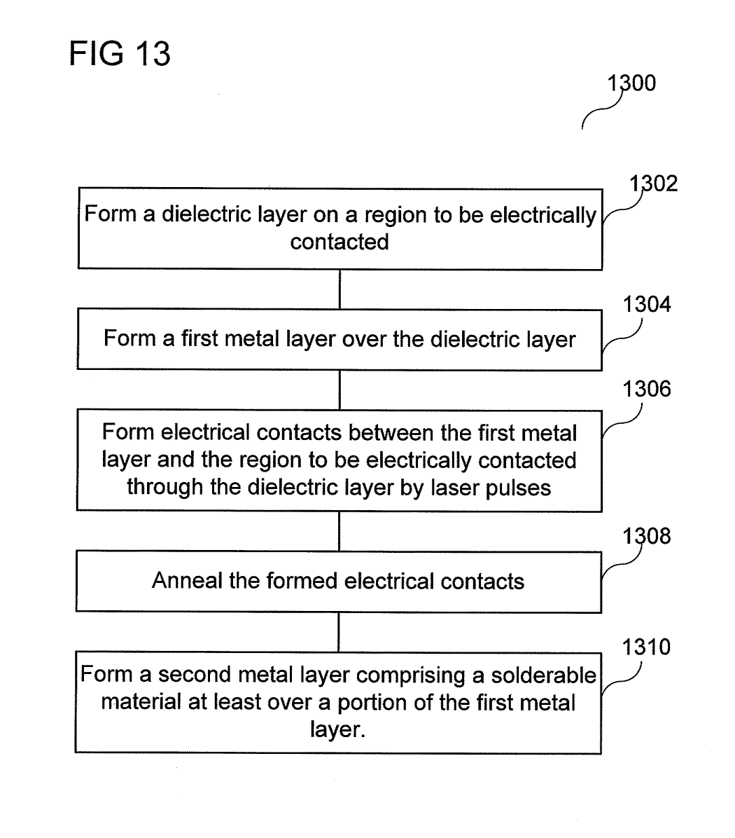

FIG. 13 shows a flow diagram 1300 illustrating a method for manufacturing of electrical contacts on a solar cell in accordance with an embodiment. The method may include, in 1302, forming a dielectric layer on a region to be electrically contacted, and, in 1304, forming a first metal layer over the dielectric layer. The method may further include, in 1306, forming electrical contacts between the first metal layer and the region to be electrically contacted through the dielectric layer by laser pulses, and, in 1308, annealing the formed electrical contacts. The method may further include, in 1310, forming a second metal layer comprising a solderable material at least over a portion of the first metal layer.

In various experiments it has been found out that the above described sequence was proven e.g. for the non contacted areas of the solar cell by good solderability of the second metal layer (e.g. nickel vanadium layer) and an excellent solder-ribbon adhesion.

Various embodiments may provide at least one of the following advantages:
Only aluminum is diffused into the bulk of the at least one photovoltaic layer 106 by the laser without bulk contamination. This may result in a good local aluminum-back surface filed (Al—BSF) for a contact point due to an optional local P⁺ doping.
The annealing of rear side contacts may be optimized without affecting the solderability the last layer(s) on the rear side of the solar cell.
The laser process window gets larger and can be optimized for lower hole depth (less bulk impact), because the conductivity between the bottom of the holes and the rear metal may strongly be supported by solderable layer(s). This may allow the use of different, cheaper laser sources.
The laser debris is covered by the solderable layer.
In various embodiments, an adhesion issue of the solderable layer is seeked to be resolved with two steps:

a) Presputtering for removal of the aluminum oxide layer formed in various embodiments;

b) Depositing a thin aluminum layer followed by depositing a solderable layer.
In various embodiments, a solderable high efficiency LFC solar cell may be provided.
In various embodiments, non contact rear metal deposition may be provided.
In various embodiments, a combination of removal of an oxidized aluminum layer with deposition of solderable layer(s) may be provided.
In various embodiments, an improvement of local fired contacts may be provided by improving the lateral conductivity.
In various embodiments, a larger process window for annealing of LFC contacts (maintaining of solderability not required) may be provided.

Various embodiments provide a process sequence for the LFC rear side of a solar cell that allows to maintain high efficiency local laser rear side contacts while achieving solderability of the solar cell.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method for manufacturing of electrical contacts on a solar cell, the method comprising:
forming a dielectric layer on a region to be electrically contacted;
forming a first metal layer over the dielectric layer;
forming electrical contacts between the first metal layer and the region to be electrically contacted through the dielectric layer by laser pulses;
annealing the formed electrical contacts; and
forming a second metal layer comprising a solderable material at least over a portion of the first metal layer.

2. The method of claim 1,
wherein the dielectric layer is formed by means of at least one of the following processes: thermal deposition, atomic layer deposition, chemical vapor deposition, or sputtering.

3. The method of claim 1,
wherein the dielectric layer comprises at least one of silicon, silicon nitride, silicon oxide, silicon carbide or aluminum oxide.

4. The method of claim 1,
wherein forming the first metal layer over the dielectric layer is carried out in a vacuum atmosphere.

5. The method of claim 1,
wherein forming the first metal layer over the dielectric layer comprises forming the first metal layer over the dielectric layer by thermal evaporation, E-beam evaporation or sputtering.

6. The method of claim 1,
wherein the solderable material comprises a material selected from a group of: nickel; nickel vanadium; chrome; nickel chrome.

7. The method of claim 1,
wherein forming the second metal layer comprising a solderable material at least over a portion of the metal layer is carried out in a vacuum atmosphere.

8. The method of claim 1,
wherein forming the second metal layer comprising a solderable material at least over a portion of the first metal layer comprises sputtering the layer comprising a solderable material.

9. The method of claim 1, further comprising:
removing a metal oxide formed from a portion of the first metal layer, e.g. by plasma treatment in a vacuum atmosphere.

10. The method of claim 9,
wherein after having removed the metal oxide, a layer of the first metal is deposited, e.g. sputtered on the first metal layer.

11. The method of claim 1,
wherein electrical contacts are formed only outside pre-defined solder pad positions.

12. The method of claim 11,
wherein the second metal layer comprising the solderable material is formed only at pre-defined solder pad positions using a mask.

13. The method of claim 1, further comprising:
forming a solder contact between a contact wire and the second metal layer comprising the solderable material.

14. A solar cell having a front side and a rear side, the solar cell comprising:
a dielectric layer on the rear side of the solar cell;
a first metal layer on the dielectric layer;
laser fired contacts forming electrical contacts between the first metal layer and the rear side of the solar cell through the dielectric layer;
a second meal layer comprising solderable material at least over a portion of the first metal layer.

15. The solar cell of claim 14,
wherein the dielectric layer comprises at least one of silicon, silicon nitride, silicon oxide, silicon carbide, and aluminum oxide.

16. The solar cell of claim 14,
wherein the first metal layer comprises at least one metal selected from a group of metals consisting of: aluminum; silver; and gold.

17. The solar cell of claim 14,
wherein the solderable material comprises a material selected from a group of: nickel; nickel vanadium; chrome; nickel chrome.

18. The solar cell of claim 14,
wherein the electrical contacts are formed only outside of pre-defined solder pad positions.

19. The solar cell of claim 14,
wherein the solderable material is formed only on pre-defined solder pad positions.

20. A method for manufacturing a rear side contact of a solar cell, the method comprising:
forming a dielectric coating on a rear side of a base region of the solar cell;
forming a metal over the dielectric coating;
carrying out a laser firing contact process to form an electrical contact between the metal and the rear side of the base region through the dielectric;
annealing the formed electrical contact; and
forming solderable material at least over a portion of the metal.
